(19) United States
(12) Patent Application Publication
(10) Pub. No.: US 2023/0352841 A1
(43) Pub. Date: Nov. 2, 2023

(54) WIRELESS SYSTEM PACKAGE

(71) Applicant: Texas Instruments Incorporated, Dallas, TX (US)

(72) Inventors: Claudia Vasanelli, Munich (DE); Hassan Ali, Murphy, TX (US); Swaminathan Sankaran, Allen, TX (US); Mohammad Vatankhah Varnoosfaderani, Dallas, TX (US); Zachary Crawford, Dallas, TX (US)

(21) Appl. No.: 18/091,295

(22) Filed: Dec. 29, 2022

Related U.S. Application Data
(60) Provisional application No. 63/337,593, filed on May 2, 2022.

(51) Int. Cl. H01Q 9/04; H01Q 1/22; H01Q 1/42

(52) U.S. Cl. CPC H01Q 9/0485; H01Q 1/2283; H01Q 1/422

(57) ABSTRACT

A device with a substrate, the substrate including opposite first and second surfaces, the first surface including metal pads, a dielectric layer between the first and second surfaces, and an opening extending through the dielectric layer and connecting between the first and second surfaces, the opening including first and second ridge structures, each of the first and second ridge structure extending with a uniform cross-section along the opening.

### CROSS-REFERENCE TO RELATED APPLICATION

This application claims the benefit of and priority to U.S. Provisional Patent Application No. 63/337,593 filed May 2, 2022, which is hereby fully incorporated herein by reference.

### BACKGROUND

A wireless system may include an integrated circuit and an antenna. The integrated circuit may transmit or receive a radio signal via the antenna. The wireless system may also include a waveguide coupled between the integrated circuit and the antenna to transmit the radio signal. In a case where the wireless system transmits/receives radio signals of multiple frequency bands/channels, the wireless system may include multiple antennas for transmission/reception of radio signals of multiple frequency bands/channels, or to separate received and transmitted radio signals. The wireless system may also include multiple waveguides coupled between the integrated circuit and the multiple antennas. Different waveguides can be isolated from each other to reduce cross coupling of radio signals between the waveguides. However, the degree of isolation can be limited by various factors, such as the form factor of the wireless system.

### SUMMARY

In one example, there is a device comprising a substrate. The substrate includes opposite first and second surfaces, the first surface including metal pads, a dielectric layer between the first and second surfaces, and an opening extending through the dielectric layer and connecting between the first and second surfaces, the opening including first and second ridge structures, each of the first and second ridge structure extending with a uniform cross-section along the opening.

In another example, there is a device comprising a substrate. The substrate includes opposite first and second surfaces, the first surface including metal pads, a first metal layer on the second surface, the first metal layer including an opening, a network of interconnects between the first and second surfaces and coupled to the metal pads, a dielectric layer between the first and second surfaces and surrounding the network of interconnects, the dielectric layer including a first dielectric material, a cavity in the dielectric layer that extends from the opening, the cavity including a second dielectric material, and a second metal layer that covers a side surface and a bottom surface of the cavity, the second metal layer joining the first metal layer.

Other aspects are also described and claimed.

### BRIEF DESCRIPTION OF THE DRAWINGS

FIG. 1A, FIG. 1B, and FIG. 1C are schematics illustrating various views of example wireless systems.

FIG. 2A and FIG. 2B are schematics illustrating a plan view of an example ridged waveguide.

FIG. 2C is a schematic illustrating a plan view of an example rectangular waveguide.

FIG. 2D is a graph illustrating properties of the example waveguides of FIGS. 2A through 2C.

FIGS. 3A, 3B, 4A, and 4B are schematics illustrating plan views of example waveguides.

FIG. 5A and FIG. 5B are schematics respectively illustrating plan and cross-sectional views of an example isolation structure abutting a waveguide.

FIG. 6A and FIG. 6B are schematics respectively illustrating plan and cross-sectional views of an example isolation structure abutting a waveguide.

FIGS. 7, 8, and 9 are schematics illustrating a cross-sectional view of example wireless systems.

FIGS. 10A and 10B are schematics illustrating cross-sectional views of respective example wireless systems.

FIGS. 11A, 11B, 11C, and 11D are schematics illustrating various views of an example printed circuit board (PCB) substrate of a wireless system.

FIGS. 12A and 12B are schematics illustrating various views of an example 3D antenna of a wireless system.

FIG. 13 is a schematic illustrating a perspective view of an example PCB substrate and an example 3D antenna of a wireless system.

The same reference numbers or other reference designators are used in the drawings to designate the same or similar (structurally and/or functionally) features. Also, some figures include a dimensional indicator, showing the x-, y-, and z-dimensions. References to these dimensions, and corresponding directionality (e.g., top, bottom, up, down, etc.), are to assist with orientation, but are not necessarily intended as a limitation.

### DETAILED DESCRIPTION

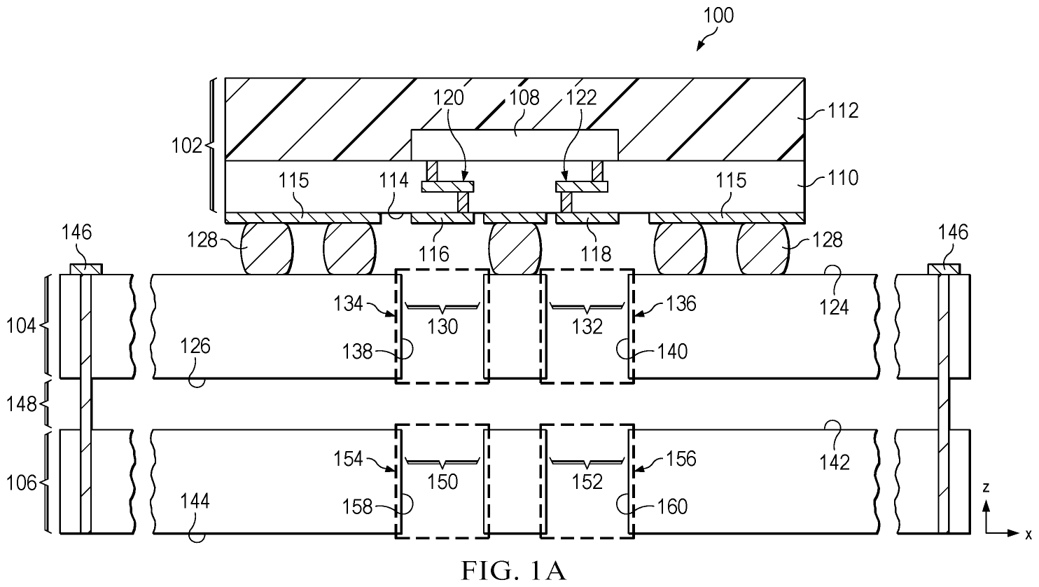

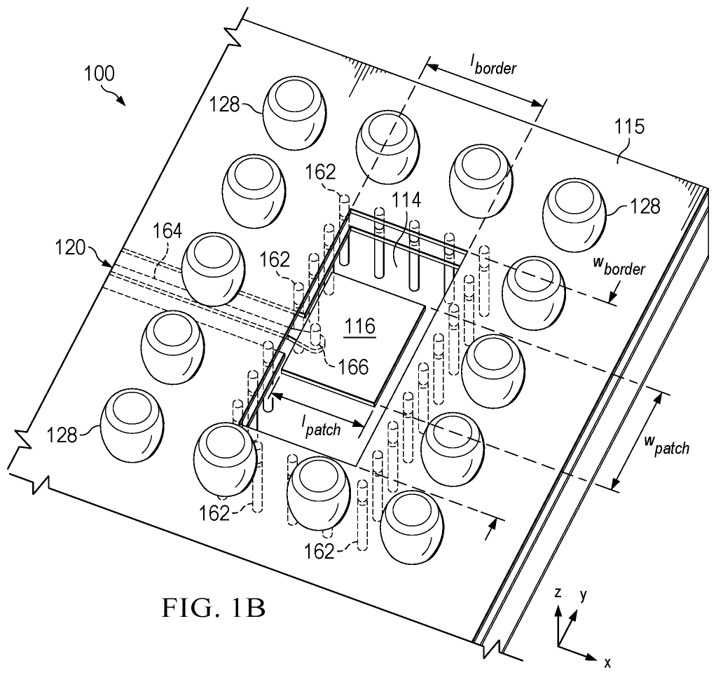

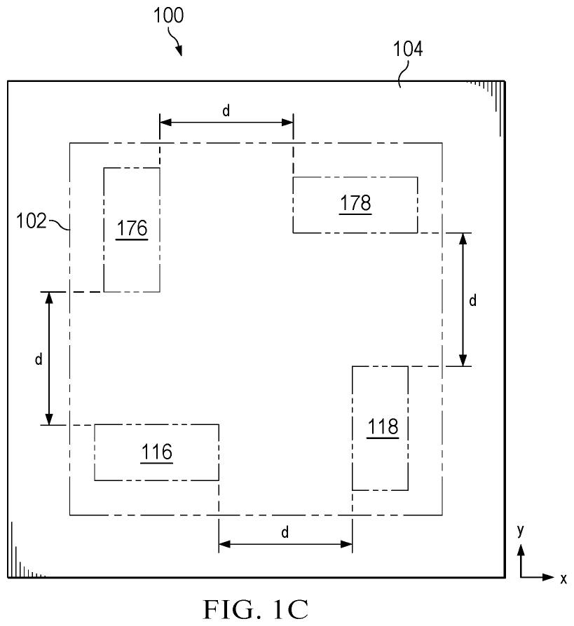

FIG. 1A is a schematic illustrating a simplified cross-sectional view of a wireless system 100, according to some examples. In some examples, the wireless system 100 can be configured to transmit and/or receive millimeter wave signals (e.g., having a frequency range of 30 GHz to 300 GHz). The wireless system 100 includes a packaged semiconductor device 102, a system substrate 104, and a 3D antenna 106, where the system substrate 104 is between and interfaces with the packaged semiconductor device 102 and the 3D antenna 106.

In some examples, the packaged semiconductor device 102, the system substrate 104, and the 3D antenna 106 can be stacked to form a launch-on-package (LoP). Specifically, the packaged semiconductor device 102 includes an integrated circuit (IC) 108, which may have both transmitting and receiving functionality. The IC 108 is partially or fully encapsulated, where the example shown includes the IC 108 on a substrate 110 that is covered with an encapsulation layer 112. The encapsulation layer 112 may include plastic, ceramic, resin, or other appropriate material. The substrate 110 has a surface 114. Portions of a metal layer 115 are along the surface 114, as are a patch 116 and a patch 118. Each of the patches 116 and 118 is connected by a respective signal path 120 and 122 to the IC 108, where the signal paths 120 and 122 may be formed as a combination of metal layer portions and vias, or striplines, as examples. The signal paths 120 and 122 facilitate wave communication. For example, the signal path 120 may be a transmit path along which the IC 108 communicates a first electrical signal for transmission by the patch 116, that is, transforming the mode propagating on the signal path 120 into a waveguide mode. Similarly, the signal path 122 may be a receive path, for receiving a second electrical signal that is received by the patch 118 and is communicated to the IC 108. The patch 116 can receive a first electrical signal from the IC 108 via the signal path 120, convert the first electrical signal to a first radio signal, and radiate the first radio signal. The patch 118 can receive a second radio signal, and convert the second radio signal to a second electrical signal, and transmit the second electrical signal to the IC 108 via the signal path 122.

The packaged semiconductor device 102 can be mounted on the system substrate 104, which can be configured as part of the LoP. The system substrate 104 has opposite surfaces 124 and 126. The surface 124 faces the surface 114 (and/or the metal layer 115 and the patches 116 and 118) of the packaged semiconductor device 102. The system substrate 104 includes an electrical insulation material between the surfaces 124 and 126. The electrical insulation material can include a dielectric material, a fiberglass material, in one or more layers, etc. In some examples, the system substrate 104 can include a printed circuit board (PCB). The system substrate 104 can include various conductors or conductive regions (e.g., metal pads) on the surfaces 124 and 126, and a network of interconnects (e.g., traces, vias, etc.) coupled between some of those regions and surrounded by the electrical insulation material. The conductors and interconnects are not shown in FIG. 1A for brevity. The packaged semiconductor device 102 can be mounted to the system substrate 104 via solder balls (or solder columns) 128, which may form part of a ball grid array (BGA).

The system substrate 104 further includes openings 130 and 132 through a thickness (e.g., in the z-dimension) of the system substrate 104, extending from the surface 124 to the surface 126, as may be filled with air. The opening 130 can be aligned with the patch 116, and the opening 132 can be aligned with the patch 118. Also, the opening 130 has sidewalls 138, and the opening 132 has sidewalls 140, where the sidewalls 138 and 140 may be metalized, as further described below. The opening 130 can provide (or can be part of) a waveguide 134 to transmit a radio signal to or from the patch 116. The opening 132 can provide (or can be part of) a waveguide 136 to transmit a radio signal to or from the patch 118. In various examples, the openings 130 and 132 may each have a particular and uniform cross-sectional shape through the thickness of the system substrate 104 between the surfaces 124 and 126.

Also, the 3D antenna 106 can be mounted on, or relative to, the system substrate 104. The 3D antenna 106 can have opposite surfaces 142 and 144, with the surface 142 facing the surface 126 of the system substrate 104. The 3D antenna 106 can include a structure formed, for example by molding or 3D printing of a material (e.g., plastic), and the surfaces of the 3D antenna 106, including the surfaces 142 and 144, can be metallized (or covered with layer of metal). In some examples, the 3D antenna 106 can also be formed as a metallic structure. The 3D antenna 106 can be mounted on the system substrate 104 based on various techniques, such as screws 146 as shown in FIG. 1A. In some examples, the 3D antenna 106 can be glued to the surface 126 of the system substrate 104 by an adhesive. A gap 148 (e.g., air gap, or a gap defined by the thickness of the adhesive) may be present between the surfaces 126 and 142. The 3D antenna 106 also can include additional portions, or be attached to an additional portion, which is not shown so as to simplify the illustration and discussion.

The 3D antenna 106 can include openings 150 and 152 formed through the thickness (e.g., in the z-dimension) of the 3D antenna 106. Each of the openings 150 and 152 can extend from the surface 142 to the surface 144. The opening 150 can have a sidewall 158 covered with metal, and the opening 152 can have a sidewall 160 covered with metal. The opening 150 can be aligned with the opening 130 of the system substrate 104, and the opening 150 can provide a waveguide 154 that connects with the waveguide 134. Also, the opening 152 can be aligned with the opening 132 of the system substrate 104, and the opening 152 can provide a waveguide 156 that connects with the waveguide 136. In various examples, the openings 150 and 152 may each have a particular and uniform cross-sectional shape through the thickness of the 3D antenna 106 between the surfaces 142 and 144. The cross-sectional shape and area of the opening 150 can match those of the opening 130 to improve the continuity of connection between the waveguides 134 and 154. Also, the cross-sectional shape and area of the opening 152 can match those of the opening 132 to improve the continuity of connection between the waveguides 136 and 156.

The LoP package of the wireless system 100, by stacking the packaged semiconductor device 102, the system package 104, and the 3D antenna 106, can provide a reduced form factor or a reduced foot print. However, the LoP package may present challenges to isolation between the waveguides 134 and 136 and between the waveguides 154 and 156. Specifically, a radio signal propagating in a waveguide (e.g., the waveguide 134) can propagate through the gap 148 to an adjacent waveguide (e.g., the waveguide 136), which can contribute to cross coupling between the waveguides. The distance/width of the gap 148 can affect the power of radio signal propagating along the gap 148 and the degree of cross coupling, and the distance/width may vary due to tolerances and/or specifications in the assembly of the LoP package. Also, to reduce the form factor of the LoP package, adjacent waveguides may be close to each other, which can reduce the propagation distance of the radio signals between the adjacent waveguides and further exacerbate the cross coupling.

FIG. 1B illustrates an example of the wireless system 100 from a perspective view of the FIG. 1A metal layer 115 and along the surface 114, showing only a partial view so that only the single patch 116 is shown. The patch 116 may be square or rectangular, having a length l_{patch} and a width w_{patch}, where for example, l_{patch}=0.82 mm and width w_{patch}=0.98 mm. The metal layer 115 provides a border that surrounds the patch 116, the border having dimensions l_{border} and w_{border}, where for example, l_{border}=1.11 mm and width w_{border}=2.15 mm. The border, and the patch 116, are surrounded by an array of solder balls 128, which by example number five in the y-dimension and four in the x-dimension. The patch 116 also may be generally surrounded by grounded vias 162. Lastly, the signal path 120 is shown to include a stripline 164 and a via 166.

FIG. 1C illustrates an example of the wireless system 100 to provide improved isolation. Referring to FIG. 1C, the packaged semiconductor device 102 may include, in addition to the patches 116 and 118, patches 176 and 178. Closest adjacent patches (and their respective waveguides with which they communicate) are separated by a distance d. Each of the patches 116, 118, 176, and 178 can transmit a radio signal having a particular polarization axis based on the orientation of the major axis (longest symmetrically located axis) of the respective patch. For example, the major axis of the patch 116 is orthogonal to the major axis of the patch 118 and, accordingly, the respective signals from those patches are cross-polarized with respect to one another. With such arrangements, a radio signal propagating from one patch and one waveguide (e.g., the patch 116 and the waveguide 134) can have an orthogonal polarization axis as the radio signal in an adjacent patch and waveguide (e.g., the patch 118 and the waveguide 136). Accordingly, a radio signal in one waveguide, if leaked into the adjacent waveguide, can be rejected by the patch over that adjacent waveguide, and cross-coupling between the adjacent waveguides can be reduced. However, the cross-polarized arrangement can increase the spacing between the patches and the waveguides, and increase the footprint of wireless system 100.

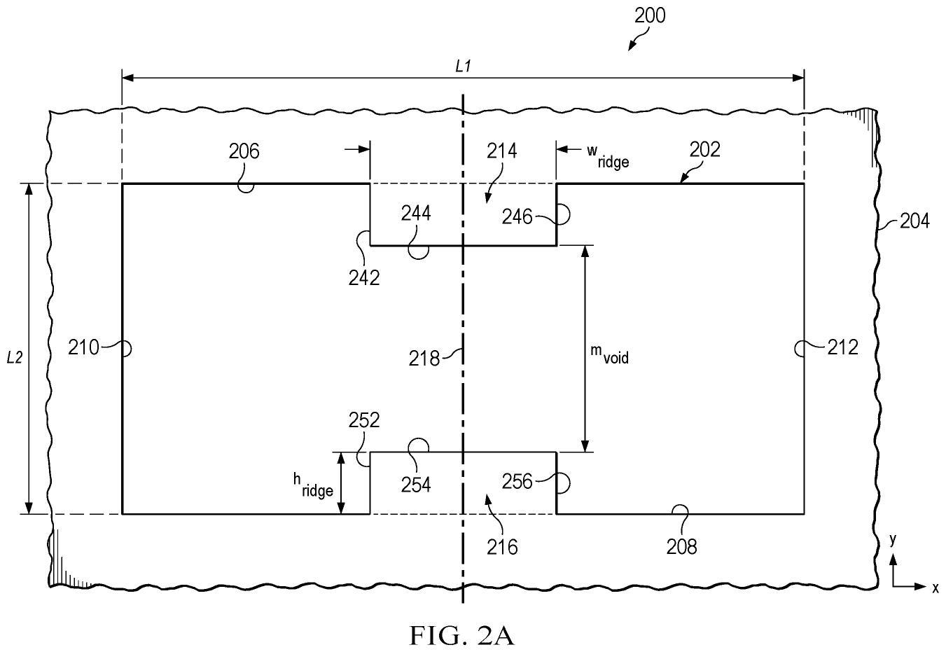

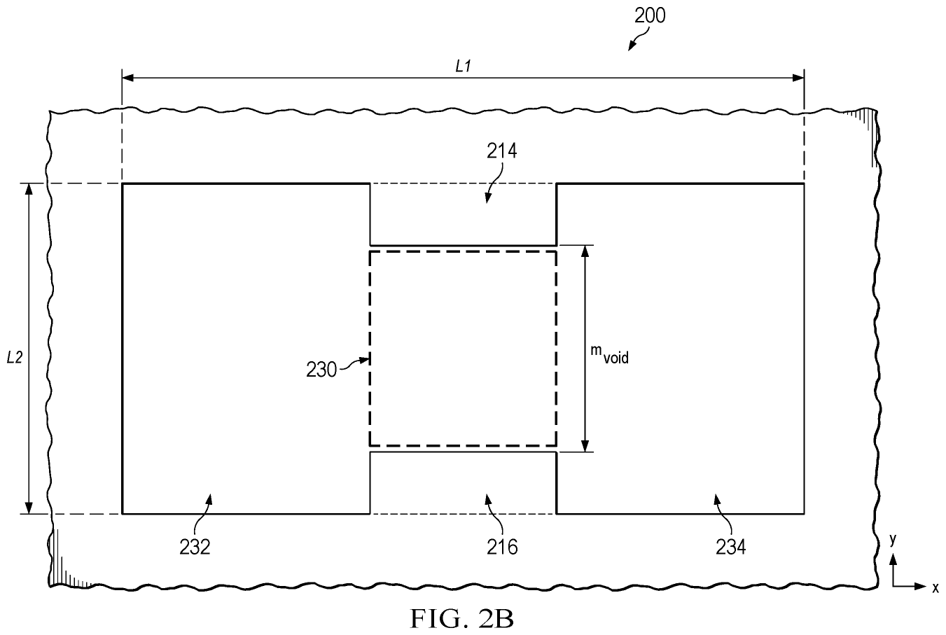

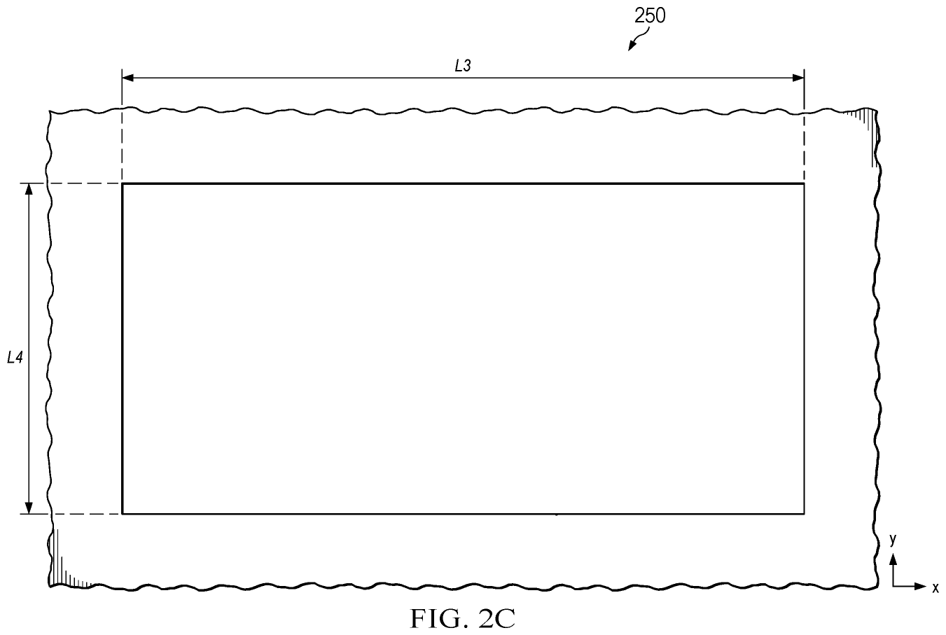

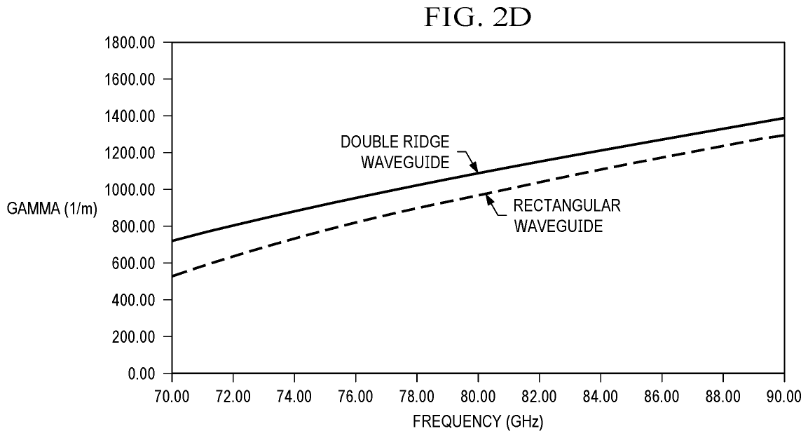

FIG. 2A is a plan view of an example waveguide 200 that can facilitate isolation against cross coupling of radio signals. FIGS. 2A and 2B illustrate the same view of the waveguide 200, but with different sets of labels denoting different features. In some examples, the waveguide 200 can be the waveguides 134/136 of the system substrate 104. In some examples, the waveguide 200 can also be the waveguides 154/156 of the 3D antenna 106. FIG. 2A illustrates a view of the cross-sectional shape of the waveguide 200 at a particular point along the thickness of the system substrate 104 or the 3D antenna 106.

Referring to FIG. 2A, the waveguide 200 can include an opening 202, which can be created by drilling, milling, a combination of both, or still other techniques. The waveguide 200 can have a footprint having a first dimension (e.g., in the x-dimension) having a length L1 and a second dimension (e.g., in the y-dimension) having a length L2. Merely by way of reference and in an example, L1 may be 2.20 mm and L2 may be 1.11 mm. In different examples, the values of L1 and L2 may be determined, for example using numerical approximation or simulations (e.g., full-wave simulations). Additional considerations regarding determining L1 and L2 may be found in “Closed-Form Expressions for the Parameters of Fined and Ridged Waveguides” by Wolfgang J. R. Hoefer and Miles N. Burton, IEEE Transactions On Microwave Theory and Techniques, Vol. MTT-30, No. 12, December 1982, which is hereby fully incorporated herein by reference. The opening 202 can include planar sidewalls 206, 208, 210, and 212 on four respective sides of the opening 202.

The waveguide 200 also includes ridges 214 and 216 that further provide the cross-sectional shape (perpendicular to the z-dimension) of the opening 202. Each of the ridges 214 and 216 can extend along the thickness (e.g., in the z-dimension of earlier Figures) of the system substrate 104 or the 3D antenna 106. The ridge 214 can have a width w_{ridge} (e.g., in the x-dimension) and extend a distance h_{ridge} away (e.g., in they-dimension) from the sidewall 206 towards the sidewall 208. Also, the ridge 216 can have the width w_{ridge} and extend the distance h_{ridge} away (also in they-dimension) from the sidewall 208 towards the sidewall 206. As with L1 and L2, described above, the values of w_{ridge} and h_{ridge} may be determined, for example, by simulation and also with consideration to the above-incorporated “Closed-Form Expressions for the Parameters of Finned and Ridged Waveguides.” Merely by way of reference and in an example, w_{ridge}=0.5 mm and h_{ridge}=0.2 mm. Accordingly, the ridges 214 and 216 can protrude inwardly and create a restricted portion 230 (see FIG. 2B) of the opening 202 having a reduced length in a particular dimension (e.g., in the y-dimension) of m_{void}, where m_{void}=L2−2*(h_{ridge}). The restricted portion 230 of the opening 202 can be between two unrestricted portions 232 and 234 of the opening 202, each unrestricted portion having the length of L2 along the particular dimension (e.g., the y-dimension). In the FIG. 2A example, the ridge 214 can have planar surfaces 242, 244, and 246, the ridge 216 can have planar surfaces 252, 254, and 256, and the opening 202 includes only planar sidewalls.

The ridges 214 and 216 can facilitate isolation between adjacent waveguides by shrinking the footprint of a waveguide to transmit a particular frequency band of radio signal. Because of the shrunk footprint of the waveguide, the separation distance between adjacent waveguides (e.g., represented by distance d in FIG. 1C) can be increased within a given footprint of the wireless system 100. The increased separation can improve isolation and reduce cross-coupling between adjacent waveguides. In some examples, the increased separation allows a co-polarized arrangement, in which the respective major axis of the patches are parallel (hence, co-polarization), which can further reduce the footprint of the wireless system 100.

Specifically, referring to FIG. 2D, it illustrates waveguide behavior across frequency on its horizontal axis and gamma (propagation constant) on its vertical axis, and it compares such behavior for a waveguide 250 having a rectangular cross-sectional area and without the ridges 214 and 216 as shown in FIG. 2C, with the waveguide 200 of FIGS. 2A and 2B. As shown in FIG. 2D, the cutoff frequency f of the FIG. 2C waveguide 250 can be related to the waveguide 250 dimensions L3 and L4 of the waveguide as follows:

$$f = \frac{c}{2 π} \sqrt{( \frac{m π}{L 3} ) + ( \frac{n π}{L 4} )} \qquad ( Equation 1 )$$

With the ridges 214 and 216, the dimensions of the waveguide 200 can be shrunk with respect to the waveguide 250 while maintaining a similar cutoff frequency f. In one example, for a similar cutoff frequency, the waveguide 250 has a footprint of L3=2.55 mm by L4=1.11 mm, and the waveguide 200 has a footprint of L1=2.20 mm by L2=1.11 mm, which represents an approximate 14% reduction of the footprint.

Ridge positioning, and the number of ridges, also may vary between various examples. In an example, the first ridge 214 and the second ridge 216 are positioned directly opposite each other, as FIG. 2A illustrates each of the ridges 214 and 216 positioned at the same point in the x-dimension along its respective planar sidewalls 206 and 208. Further, in one example, and as illustrated in FIG. 2A, the ridges 214 and 216 can be aligned along a center line 218 of the opening 202, and the cross-sectional area of the opening 202 can be symmetrical about the center line 218. Further, in some examples, the waveguide 200 can include a single ridge (e.g., one of the ridges 214 or 216).

The ridge dimensions can be configured to achieve a particular set of waveguide attributes, including cutoff frequency and bandwidth. As explained above, the lengths of L1 and L2 may set a cutoff frequency and bandwidth of the waveguide in its fundamental mode. Further, h_{ridge} may strongly control the cutoff frequency of the fundamental mode, that is, the larger h_{ridge}, the smaller the cutoff frequency, and vice versa. Further, w_{ridge} can also shift the cutoff frequency, although not as strongly as h_{ridge}. Also, the value of w_{ridge} can be inversely proportional to cutoff frequency. In addition, md results from adjustment of these other considerations, that is, from L2, h_{ridge}, and w_{ridge}.

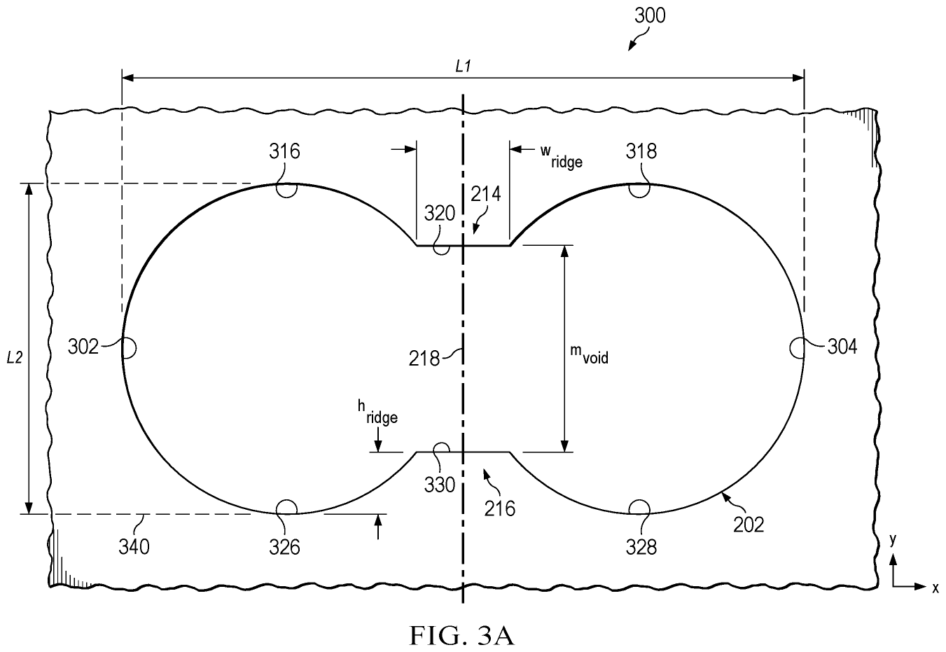

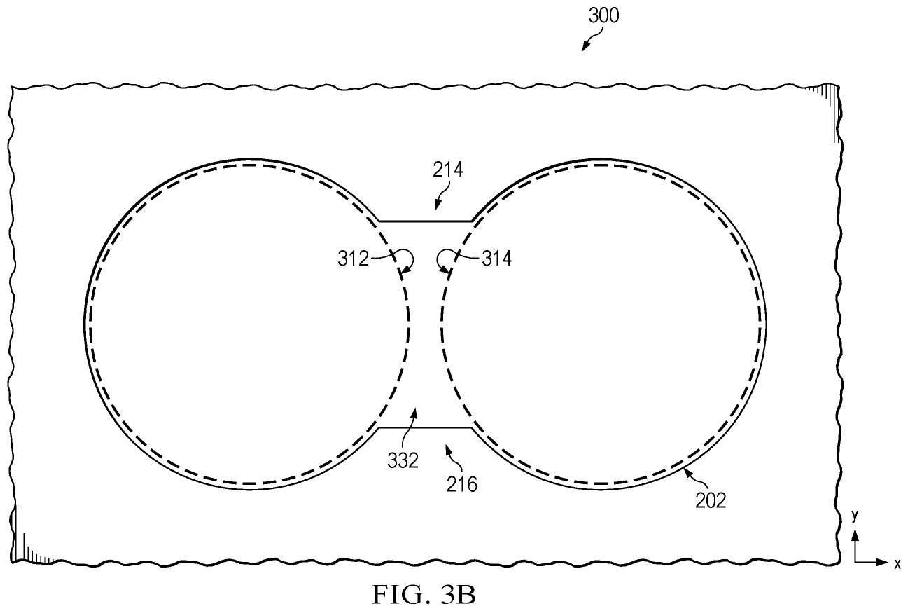

FIGS. 3A and 3B are plan views of another example waveguide 300 having ridges in the opening 202, as possible implementation for the FIGS. 2A/2B example waveguide 200, taking into account milling and drilling of the waveguide shape. FIGS. 3A and 3B illustrate the same cross-sectional view of the waveguide 300 but with different sets of labels denoting different features. In some examples, the waveguide 300 can be the waveguides 134/136 of the system substrate 104. In some examples, the waveguide 300 can also be the waveguides 154/156 of the 3D antenna 106. FIGS. 3A and 3B illustrate the cross-sectional shape of the waveguide 300 at a particular point along the thickness of the system substrate 104 or the 3D antenna 106.

The waveguide 300 can have a footprint of L1×L2. The waveguide 300 includes the opening 202 and the ridges 214 and 216. In the example of FIG. 3, the opening 202 can have curved sidewalls 302 and 304 that define circular portions 312 and 314 of the opening 202. The ridge 214 has curved surfaces 316 and 318 that extend respectively from the curved sidewalls 302 and 304, and a top surface 320 coupled between curved surfaces 316 and 318. The ridge 216 has surfaces 326 and 328 that extend respectively from the curved sidewalls 302 and 304, and a top surface 330 coupled between the curved surfaces 326 and 328. The ridges 214 and 216 can define a restricted portion 332 (FIG. 3GB) of the opening 202 between the circular portions 312 and 314. In the example of FIGS. 3A and 3B, both the top surfaces 320 and 330 can be planar, and the respective width of each top surface (e.g., in the x-dimension) can define w_{ridge}. Further, a distance between a top surface (e.g., top surface 330) and the nearest parallel tangent line to the circular regions 312/314 (e.g., tangent line 340) can define h_{ridge}. The diameter of each of circular regions 312 and 314 can be less than 0.5*L1. The opening 202 can be symmetric over the center line 218.

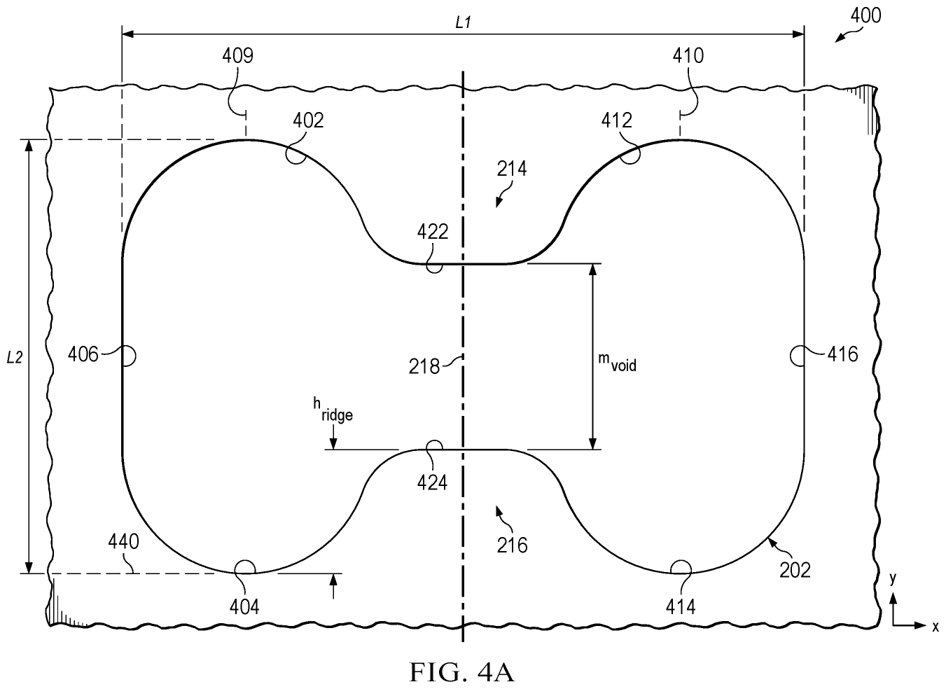

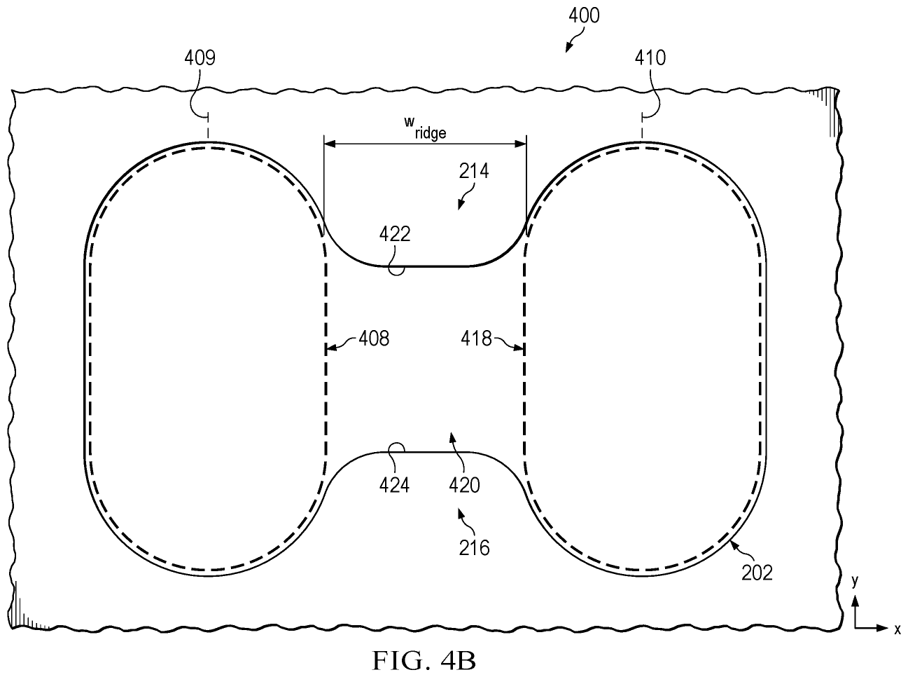

FIGS. 4A and 4B are plan views of another example waveguide 400 having the ridges 214 and 216 in the opening 202, again as possible implementation for the FIGS. 2A/2B example waveguide 200, taking into account milling and drilling of the waveguide shape. FIGS. 4A and 4B illustrate the same cross-sectional view of the waveguide 400 but with different sets of labels denoting different features. FIGS. 4A and 4B illustrate the cross-sectional shape of the waveguide 400 at a particular point along the thickness of the system substrate 104 or the 3D antenna 106. In some examples, the waveguide 400 can be waveguides 134/136 of the system substrate 104. In some examples, the waveguide 400 can also be waveguides 154/156 of the 3D antenna 106.

Referring to FIG. 4A, the waveguide 400 can have a footprint of L1×L2. The waveguide 400 includes the opening 202 and the ridges 214 and 216. The waveguide 400 includes curved sidewalls 402, 404, and a planar sidewall 406 that defines an oblong circular region 408 of the opening 202. The waveguide 400 also includes curved sidewalls 412, 414, and a planar sidewall 416 that defines an oblong circular region 418 of the opening 202. The ridges 214 and 216 can define a restricted region 420 of the opening 202. The ridge 214 includes a top surface 422, and the ridge 216 includes a top surface 424. A distance between the nearest linear boundaries of oblong circular regions 408 and 418 can define w_{ridge}. Also, a distance between a top surface (e.g., the top surface 424) and the nearest parallel tangent line to the oblong circular regions 408/418 (e.g., the tangent line 440) can define h_{ridge}. The opening 202 can be symmetric over the center line 218.

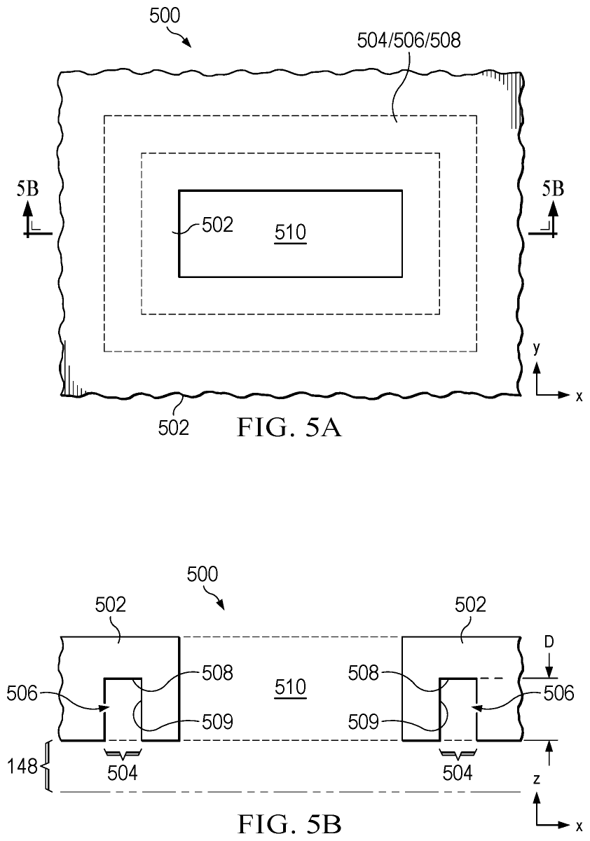

FIG. 5A and FIG. 5B are schematics illustrating plan and cross-sectional views of an example isolation structure 500 either surrounding or abutting a waveguide, such as one of the waveguides 138, 140, 154, 156, 200, 300, and 400. FIG. 5A is a plan view, and FIG. 5B is a cross-sectional view. The isolation structure 500 can be part of the system substrate 104 and has a surface 502 that interfaces with the gap 148. The isolation structure 500 can include an opening 504 on the surface 502, and a cavity 506 that extends from the opening 504. The cavity 506 has a bottom surface 508 and sidewalls 509. The cavity 506, or its sidewall 509, can abut an opening 510 of the waveguide. The bottom surface 508 and the sidewalls 509 can be covered with a metal layer. In some examples, the cavity 506 can be filled with an electrical insulation material, such as a dielectric material.

In the example of FIG. 5A and FIG. 5B, the cavity 506 can be configured as a short circuit stub to trap a radio signal that propagates along the gap 148, to prevent (or attenuate) the cross-coupling of radio signals between adjacent waveguides. The short circuit stub can provide a propagation distance equal to odd multiples (e.g., 1, 3, or 5) of a quarter wavelength (λ/4) of the radio signal prior to the radio signal being reflected. In the example of FIG. 5A and FIG. 5B, the cavity 506 can have a depth D equal to odd multiples of λ/4. The radio signal out of the opening 510 can propagate through the gap 148 and enter the cavity 506 via the opening 504. The radio signal can propagate along a vertical direction (e.g., along the z-dimension) and can be reflected at the bottom surface 508, which may be covered with a metal layer and provides the short circuit termination of the stub. The reflected radio signal can superimpose with the incident radio signal. The depth D of the cavity 506 can set the phase difference between the reflected and incident radio signals at odd multiples of λ/4. Destructive interference can take place, and the radio signal can be trapped and prevented from entering an abutting waveguide, which can reduce the cross-coupling between adjacent waveguides.

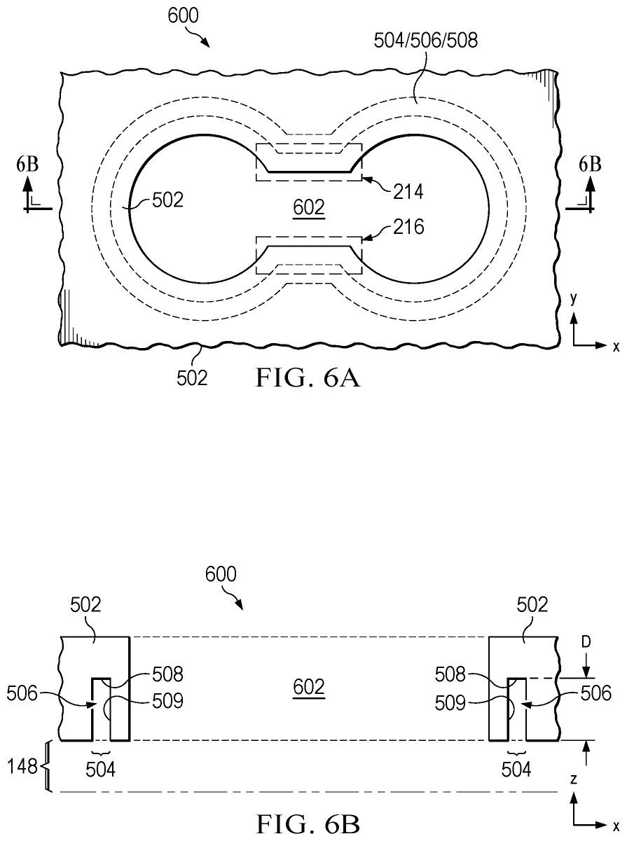

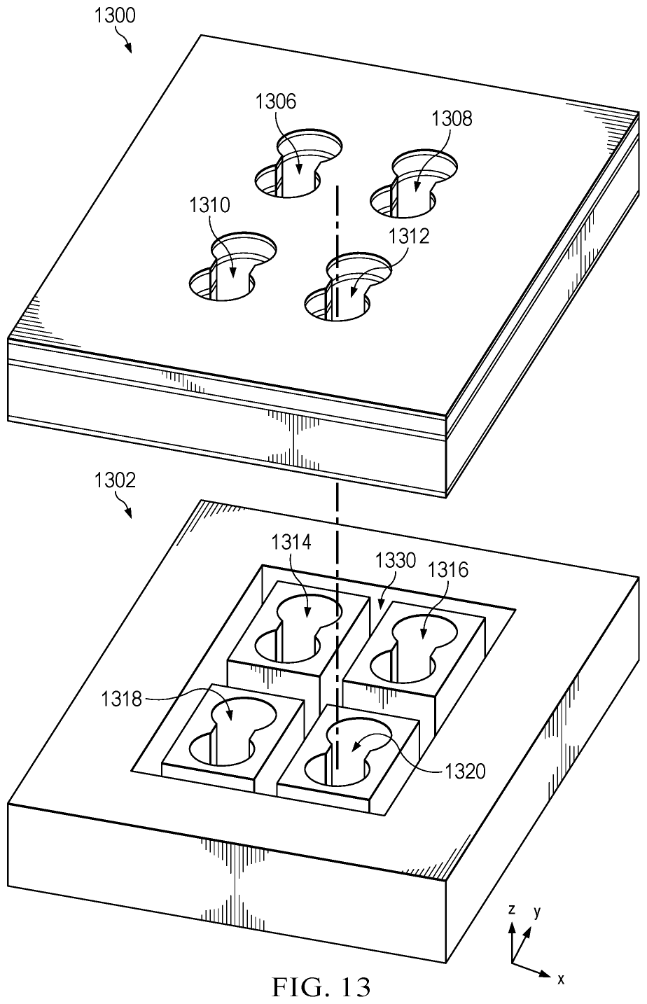

In some examples, the opening 504/cavity 506 can extend along one side of the opening 510 to provide isolation between two adjacent waveguides along one direction. In some examples, referring to FIG. 5A, the opening 504/cavity 506 can extend around the opening 510 of the waveguide, for example in the form of a trench, to provide isolation between adjacent waveguides along multiple directions. In FIG. 5A and FIG. 5B, the opening 504/cavity 506 can have a rectangular cross-sectional shape, and the isolation structure 500 can include a trench having a rectangular contour. In FIG. 6A and FIG. 6B, the waveguide can include ridges 214 and 216 that define the cross-sectional shape of an opening 602, and the trench provided by the opening 504/cavity 506 can have a contour that matches the shape of the opening 602. In an alternative, the shape of the opening 504/cavity 506 need not necessarily match the shape of the opening 602, as shown later by example in FIG. 13.

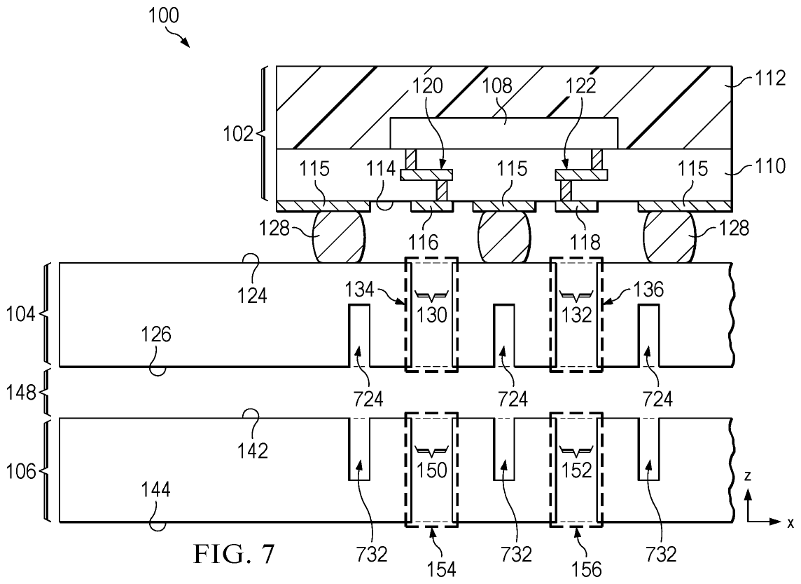

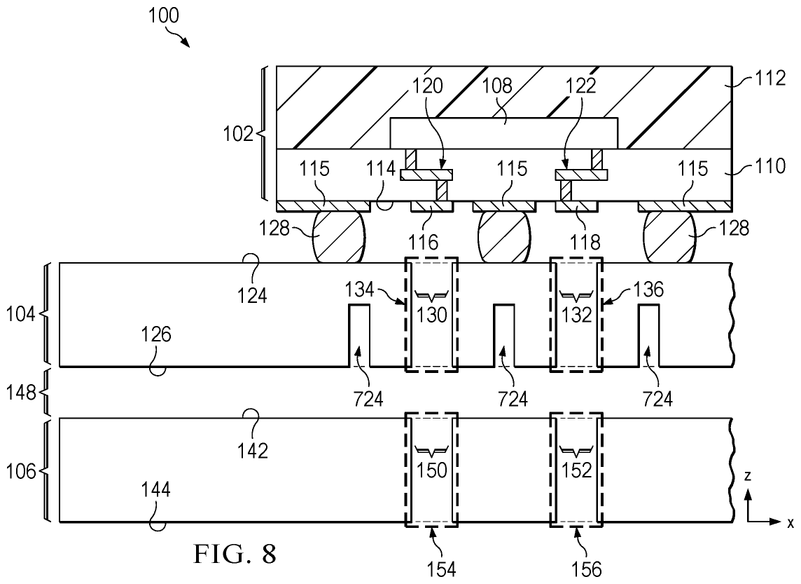

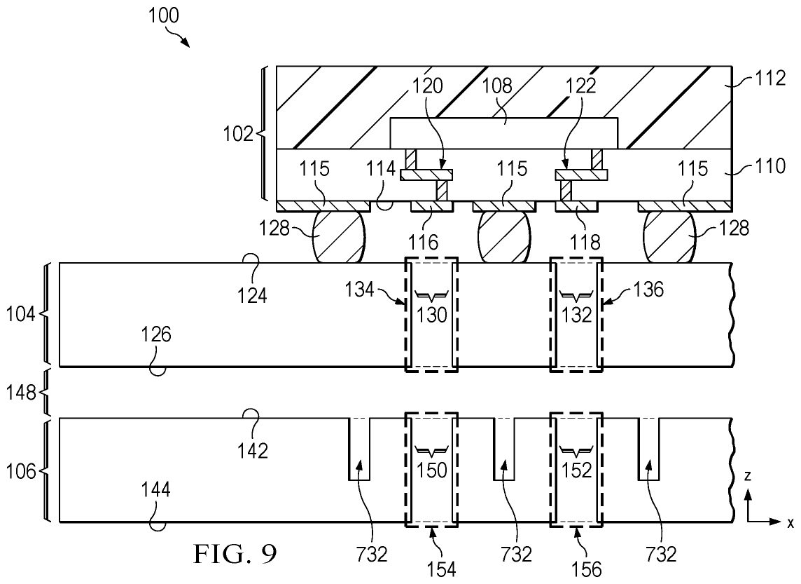

The isolation structures 500 and 600 of FIG. 5A through FIG. 6B can be implemented as part of the system substrate 104, as part of the 3D antenna 106, or both. FIGS. 7, 8, and 9 illustrate examples of the wireless system 100 including isolation structures. Referring to FIG. 7, the system substrate 104 can include short circuit stubs 724 as part of the isolation structures 500/600, and the 3D antenna 106 can include short circuit stubs 732 as part of the isolation structures 500/600. Both of the short circuit stubs 724 and 732 can include cavities having an opening that interfaces with the gap 148. Each of the cavities of the short circuit stubs 724 and 732 can have sidewalls and a bottom surface covered with metal. Each of the cavities of the short circuit stubs 724 and 732 can have a depth (e.g., along the z-dimension) equal to odd multiples of λ/4, or otherwise provide a propagation distance equal to odd multiples of λ/4 for the radio signal between the opening and the location of reflection. The system substrate 104 can include a short circuit stub 724 between adjacent waveguides 134 and 136 to improve isolation between the adjacent waveguides. The 3D antenna 106 can also include a short circuit stub 732 between adjacent waveguides 154 and 156 to improve isolation between the adjacent waveguides. FIG. 8 illustrates a cross-sectional view of another example of the wireless system 100 where the system substrate 104 includes the short circuit stubs 724 and the 3D antenna 106 does not include short circuit stubs interfacing the gap 148. FIG. 9 illustrates a cross-sectional view of another example of the wireless system 100 where the 3D antenna 106 includes the short circuit stubs 732, and the system substrate 104 does not include short circuit stubs interfacing the gap 148.

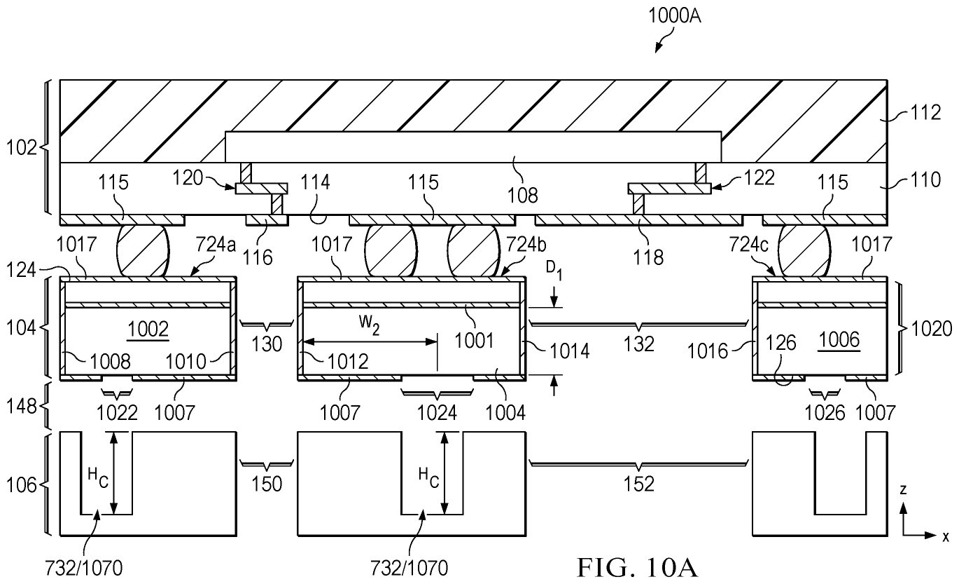

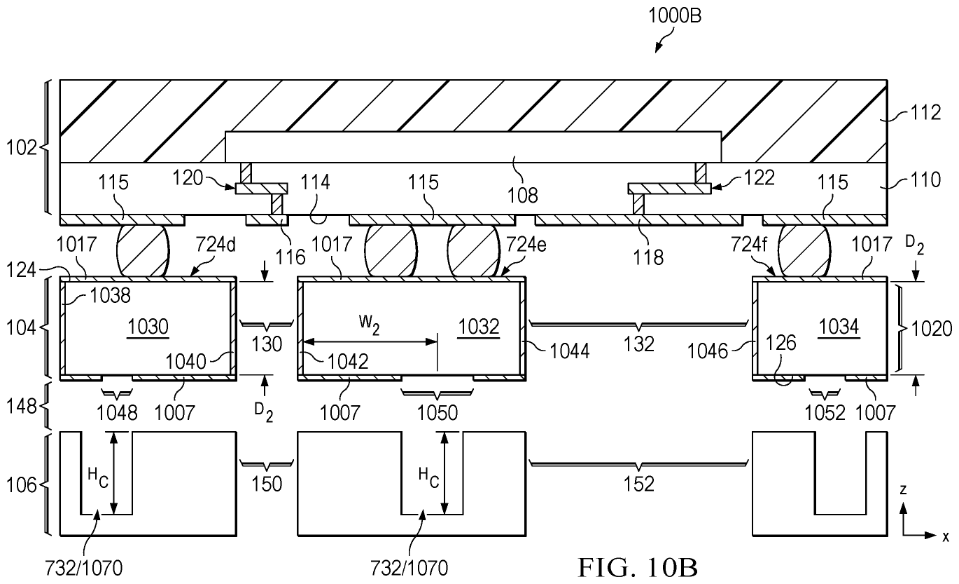

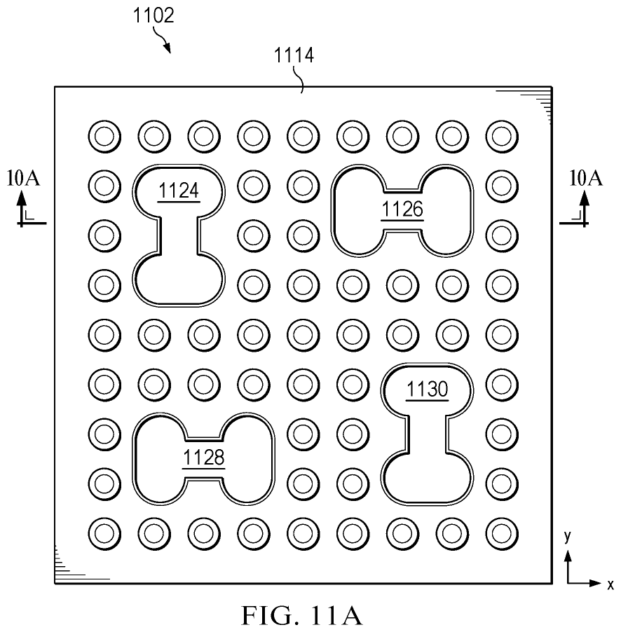

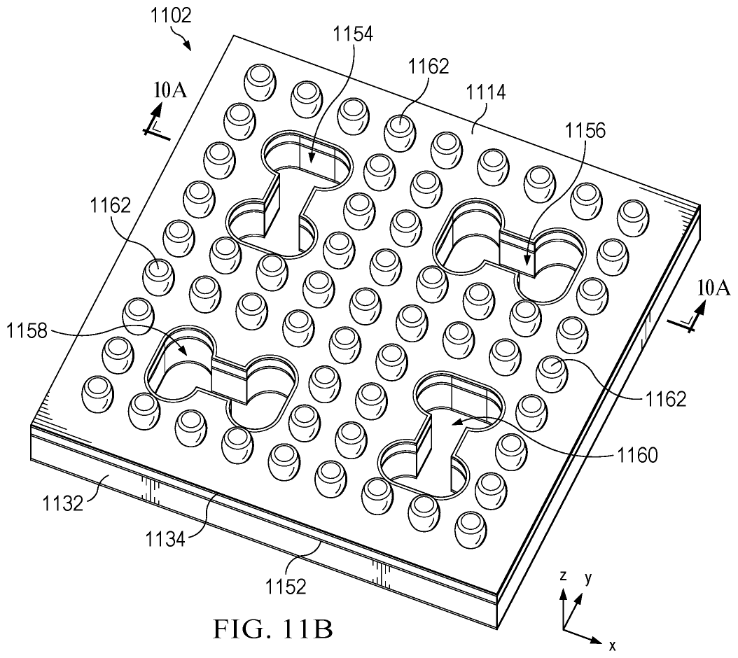

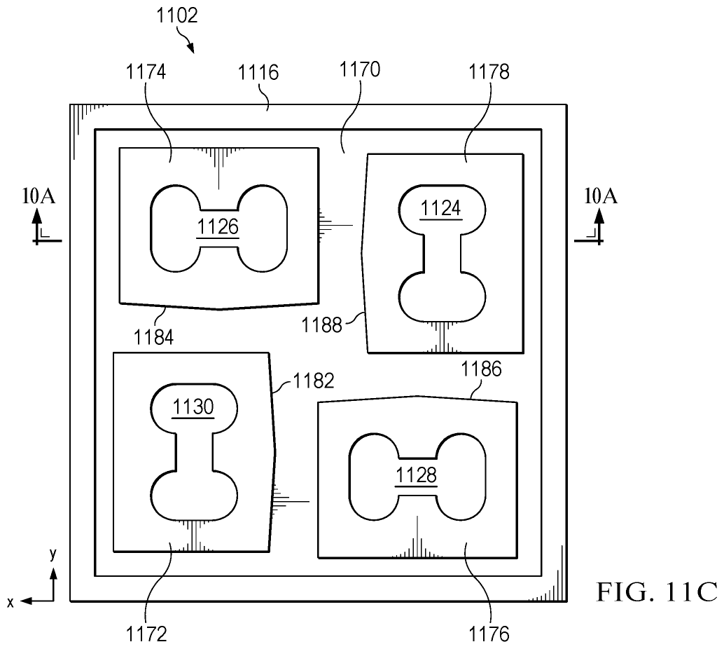

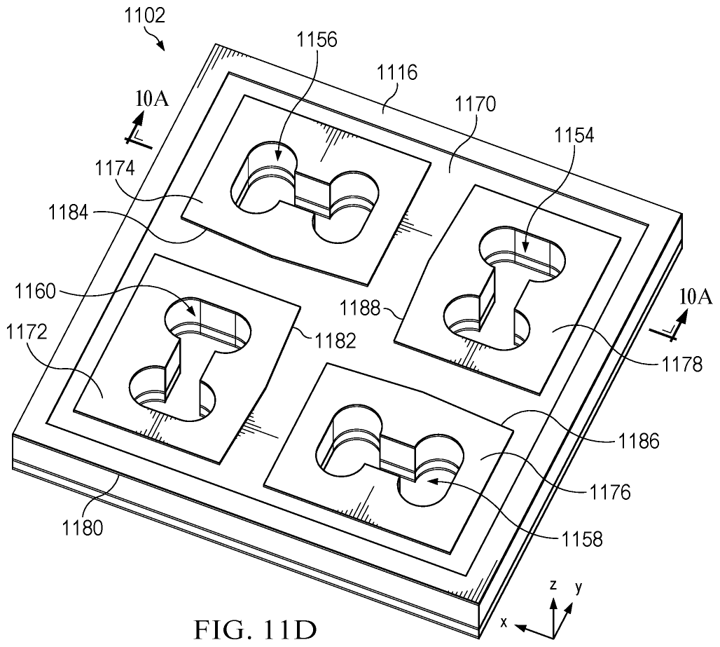

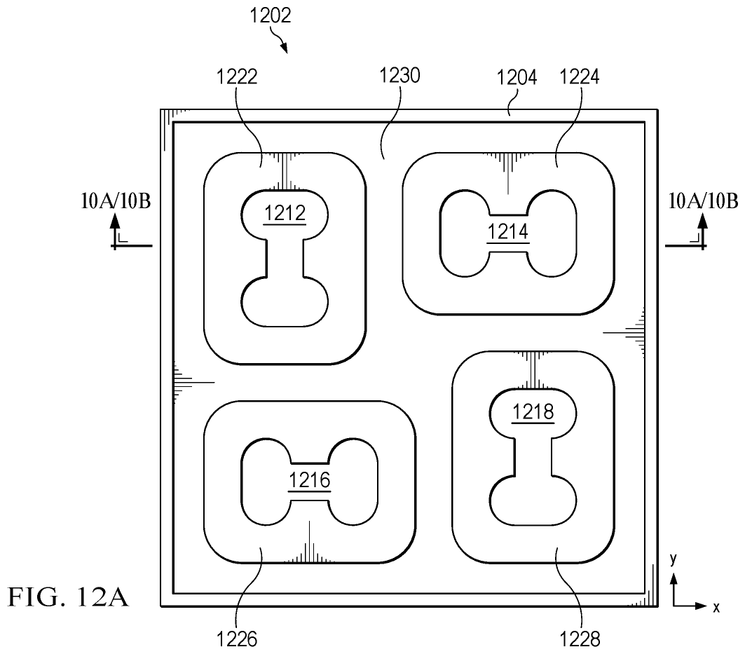

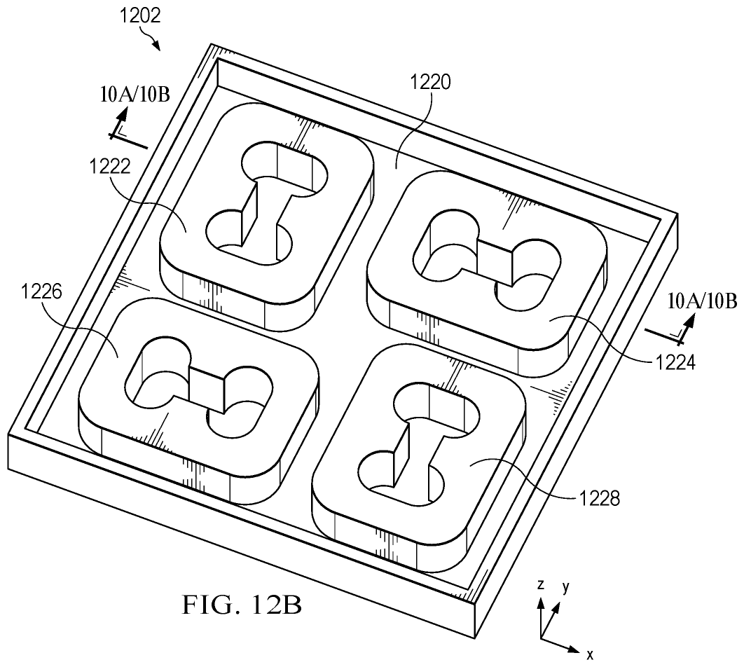

FIGS. 10A and 10B are schematics, illustrating a first example 1000A and a second example 1000B, of the short circuit stubs 724 and 732 of the wireless system 100. Generally, the FIG. 10A cross-section is positioned as shown in later FIGS. 11A through 12B, while FIG. 10B includes alternative structural options in the system substrate 104. In both FIGS. 10A and 10B, the examples 1000A and 1000B depict cross-sectional views of the patches 116 and 118 from a perspective of different respective widths (e.g., along the x-dimension), which are matched by the different widths between the openings 130 and 132 and between the openings 158 and 160. FIG. 10A illustrates three examples of short circuit stubs 724a, 724b, and 724c of the system substrate 104 interfacing with the gap 148, and FIG. 10B illustrates three examples of short circuit stubs 724d, 724e, and 724f of the system substrate 104 interfacing with the gap 148. Each of the short circuit stubs 724a, 724b, and 724c, or 724d, 724e, and 724f, can be integrated (or be part of) in the system substrate 104. Each of the FIG. 10A short circuit stubs 724a, 724b, and 724c can extend through part of the thickness of the system substrate 104, and each of the FIG. 10B short circuit stubs 724d, 724e, and 724f can extend through the entire thickness of the system substrate 104. The difference between FIGS. 10A and 10B is that FIG. 10A includes a metal layer 1001 within the system substrate 104, and that metal layer 1001 defines a depth D₁ of the cavity formed by each of the short circuit stubs 724a, 724b, and 724c, whereas FIG. 10B does not include such a metal layer between its outermost surfaces, so that a depth D₂ exists in the cavity formed by each of the short circuit stubs 724d, 724e, and 724f.

In FIG. 10A, each of the short circuit stubs 724a, 724b, and 724c can have a respective cavity 1002, 1004, and 1006 that extends between a metal layer 1007 on the surface 126 of the system substrate 104 and the metal layer 1001, that is, only through a partial thickness of the dielectric of the system substrate 104. In FIG. 10A, each of the cavities 1002, 1004, and 1006, can correspond to the cavity 506 of FIGS. 5B and 6B. The cavity 1002 also can include metal sidewalls 1008 and 1010, the cavity 1004 can include metal sidewalls 1012 and 1014, and the cavity 1006 can include a metal sidewall 1016, but to the right in FIG. 10A, the cavity 1006 includes an area 1020 that is shown to exclude a metal sidewall, as isolation (e.g., high impedance) may be provided in the area 1020 by the dielectric extending in the x-dimension, or by air, or alternatively a metal sidewall may be included thereon. The metal sidewalls 1008 and 1010 (or 1012 and 1014, or 1016) can extend to and join a metal layer 1017 on the surface 124 of the system substrate 104. Any of the metal sidewalls may abut an opening of a waveguide and become part of the sidewall of the waveguide. For example in the cavity 1002, the metal sidewall 1010 abuts the opening 130 and can be part of the sidewall 138 of the waveguide 134 in FIG. 1A. The metal layer 1007 also includes an opening 1022 of the cavity 1002. Similarly, the metal layer 1007 also includes an opening 1024 of the cavity 1004 and an opening 1026 of the cavity 1006. Each of the openings 1022, 1024, and 1026 interfaces with the gap 148, and each faces the metal layer 1001, so that each opening can correspond to the opening 504 of FIGS. 5B and 6B.

In FIG. 10B, each of the short circuit stubs 724d, 724e, and 724f can have a respective cavity 1030, 1032, and 1034 that extends between the metal layer 1007 on the surface 126 of the system substrate 104 and the metal layer 1017 on the surface 124, that is, fully through the thickness of the dielectric of the system substrate 104. In FIG. 10B, each of the cavities 1030, 1032, and 1034 can correspond to the cavity 506 of FIGS. 5B and 6B. The cavity 1030 also can include metal sidewalls 1038 and 1040, the cavity 1032 also can include metal sidewalls 1042 and 1044, and the cavity 1034 can include a metal sidewall 1046, and it can include the area 1060 without (or with) a metal sidewall. Any of the metal sidewalls may abut an opening of a waveguide and become part of the sidewall of the waveguide. For example in the cavity 1030, the metal sidewall 1040 abuts the opening 130 and can be part of the sidewall 138 of the waveguide 134 in FIG. 1A. The metal layer 1007 also includes an opening 1048 of the cavity 1030. Similarly, the metal layer 1007 also includes an opening 1050 of the cavity 1032 and an opening 1052 of the cavity 1034. Each of the openings 1048, 1050, and 1052 interfaces with the gap 148, and each faces the metal layer 1017, so that each opening can correspond to the opening 504 of FIGS. 5B and 6B.

In some examples, in either or both of FIGS. 10A and 10B, some or all of each of the cavities 1002, 1004, and 1006, or 1030, 1032, and 1034, can be filled with an electrical insulation material, such as a dielectric material, a fiberglass material, etc., and the electrical insulation material can be exposed at the respective opening 1022, 1024, and 1026, or 1048, 1050, and 1052. A radio signal propagating along the gap 148 can enter any of the cavities 1002, 1004, and 1006, or 1030, 1032, and 1034, via its respective opening 1022, 1024, and 1026, or 1048, 1050, and 1052. In FIG. 10A, such an entering signal may be reflected at the metal layer 1001, which can be a short circuit termination, and likewise in FIG. 10B, such an entering signal may be reflected at the metal layer 1017. To enable destructive interference between the incident and reflected radio signals, the depth D₁ of each of the cavities 1002, 1004, and 1006, or the depth D₂ of each of the cavities 1038, 1040, and 1042, can be an odd multiple of λ/4 of the radio signal. In some examples, the FIG. 10A metal layer 1001 can be provided in the system substrate 104 to define the depth D₁, if the depth of the thickness of the system substrate 104 does not match (or approximate) an odd multiple of λ/4 of the radio signal. Accordingly, a radio signal propagating along the gap 148 can enter any of the cavities and is reflected by a metal layer (1001 in FIG. 10A, 1017 in FIG. 10B), which can be the short circuit termination and enable destructive interference between the incident and reflected radio signals, for example in response to the depths D₁ or D₂, respectively. Additionally, in some examples, a radio signal propagating along the gap 148 and that enters a cavity via its opening may propagate towards one of the respective sidewalls and is reflected at the sidewall as a short circuit termination. For example, in FIG. 10A, such a signal may enter the opening 1022 of the cavity 1002 and reflect off the sidewalls 1008 and 1010. As another example, in FIG. 10B, such a signal may enter the opening 1048 of the cavity 1030 and reflect off the sidewalls 1038 and 1040. To enable destructive interference between the incident and reflected radio signals, the distance between the sidewall to provide the short circuit termination (e.g., sidewall 1012) and the opening 1024, labelled W₂ in FIG. 10A (or between the sidewall 1042 and the opening 1050 in FIG. 10B), can be an odd multiple of λ/4 of the radio signal. In some examples, a combination of D₁ and W₂, or D₂ and W₂, can also be an odd multiple of λ/4 of the radio signal to account for additional distances traversed by the radio signal prior to reflection.

In addition, the 3D antenna 106 can include cavities 1070 that interface with the gap 148 to provide the short circuit stubs 732. Each cavity 1070 can have internal surfaces (e.g., sidewalls and bottom surface) covered with a metal layer, and the depth H_{C} of the cavity can be an odd multiple of λ/4 of a radio signal that propagates through the gap 148.

FIGS. 11A through 11D illustrate various views of a PCB substrate 1102, as an example including certain aspects introduced above. The PCB substrate 1102 can be an example of the system substrate 104 of the wireless system 100 of FIGS. 1A through 10B. Specifically, FIG. 11A provides a plan view of a surface 1114 of the PCB substrate 1102 interfacing the packaged semiconductor device 102 (e.g., the surface 124 of the system substrate 104), and FIG. 11B provides a perspective view of the PCB substrate 1102 including the surface 1114. Also, FIG. 11C provides a plan view of a surface 1116 of the PCB substrate 1102 interfacing a 3D antenna (e.g., the surface 126 of the system substrate 104), and FIG. 11D provides a perspective view of the PCB substrate 1102 including the surface 1116. The PCB substrate 1102 includes openings 1124, 1126, 1128, and 1130. Each of the openings 1124, 1126, 1128, and 1130 can correspond/represent one of the openings of a system substrate described above (e.g., openings 134, 136, 154, 156, 202, 510, and 602).

In the illustrated example, each of the openings 1124, 1126, 1128, and 1130 has a pair of ridges, which provide an approximate figure-8 shape for each of the openings. Further, in the illustrated example, each of the openings 1124, 1126, 1128, and 1130 is oriented so that its major axis (longest symmetrically located axis) is orthogonal to the major axis of its nearest (or plural nearest) other opening(s). This orthogonal orientation provides cross-polarization between waves traveling through one waveguide, relative to the wave, or respective wave, in a neighboring waveguide(s), as may improve signal isolation between those waveguides.

Referring to FIG. 11B, the PCB substrate 1102 includes a dielectric layer 1132. A metalized layer 1134 provides the surface 1114, and the metalized layer 1134 may have a thickness in a range of 15 μm to 35 μm, or greater. In an example, the openings 1124, 1126, 1128, and 1130 are first formed through the entire thickness of the dielectric layer 1132 (in the z-dimension), after which the upper surface 1114 is metalized and thereby creates the metalized layer 1134. The metallization also is formed (concurrently or in a separate step and/or process) over sidewalls 1154, 1156, 1158, and 1160 of the respective openings 1124, 1126, 1128, and 1130. In some examples, an intermediate metal layer 1152 is also formed in the x/y plane, that is in parallel orientation to the surface 1114, but at some depth (e.g., in the z-dimension) and within the dielectric layer 1132, or separating the dielectric layer into separate layers. Further, the PCB substrate 1102 can include solder balls (or solder columns) 1162 on the surface 1114. The solder balls 1162 can provide electrical connection between traces/vias in the PCB substrate 1102. The solder balls 1162 can be insulated from the metalized layer 1134 by an insulation layer (e.g., solder mask) not shown in the figures.

FIG. 11C provides a plan view of the surface 1116 of the PCB substrate 1102, and FIG. 11D provides a perspective view of the PCB substrate 1102 including the surface 1116. Referring to FIGS. 11C and 11D, the PCB substrate 1102 includes an isolation structure 1170 on the surface 1116. The isolation structure 1170 can include a set of cavities/trenches abutting the sidewalls 1154, 1156, 1158, and 1160 of the openings, and can include short circuit stubs such as the short circuit stubs 724 of FIG. 10A. The set of cavities/trenches of the isolation structure can be filled with a dielectric material same as the dielectric layer 1132. The surface 1116 can include the metal layers 1172, 1174, 1176, 1178, and 1180, and opposite edges of the metal layers can define the opening of the cavities/trenches of the isolation structure 1170. Also, the metal layer 1172 can surround the opening 1130, the metal layer 1174 can surround the opening 1126, the metal layer 1176 can surround the opening 1128, and the metal layer 1178 can surround opening the 1130. In some examples, some of the metal layers can include angled edges to create a cavity opening having a restricted portion (e.g., an opening with an hour glass shape) to improve the bandwidth of the waveguides. For example, the metal layer 1172 can include angled edges 1182, the metal layer 1174 can include angled edges 1184, the metal layer 1176 can include angled edges 1186, and the metal layer 1178 can include angled edges 1188.

FIGS. 12A and 12B illustrate various views of an example 3D antenna 1202, or a portion thereof, which can be mounted on the surface 1116 of the PCB substrate 1102 of FIGS. 11A through 11D. Specifically, FIG. 12A provides a plan view of a surface 1204 of the 3D antenna 1202 interfacing the PCB substrate 1102, and FIG. 12B provides a perspective view of the 3D antenna 1202 including the surface 1204. The 3D antenna 1202 includes openings 1212, 1214, 1216, and 1218. Each of the openings 1212, 1214, 1216, and 1218 can correspond/represent one of the openings of a 3D antenna described above (e.g., openings 150, 152, 202, 510, and 602). The 3D antenna 1202 includes waveguides 1222, 1224, 1226, and 1228 including the respective openings 1212, 1214, 1216, and 1218. The 3D antenna 1202 can include a metallic structure, or can be have surfaces coated/plated with a layer of metal.

As shown in FIGS. 12A and 12B, the 3D antenna 1202 includes an isolation structure 1230 in connection with the surface 1204. The isolation structure 1230 can include a set of cavities/trenches abutting the waveguides 1222, 1224, 1226, and 1228, and can include short circuit stubs such as short circuit stubs 734 of FIGS. 10A and 10B.

FIG. 13 is a perspective view of an example of PCB substrate 1300 and 3D antenna 1302 that can be part of a wireless system, such as the wireless system 100. In FIG. 13, the PCB substrate 1300 includes openings 1306, 1308, 1310, and 1312, each with a pair of ridge structures, which provide an approximate figure-8 shape for each of the openings. Each of the openings 1306, 1308, 1310, and 1312 is oriented with each with its major axis parallel to the major axis of its nearest (or plural nearest) other opening(s), in a co-polarized arrangement. As explained above, because of the ridge structures, the footprint of each opening (and the waveguide) can be shrunk to increase the separation distance between the openings. This allow the openings to be oriented in a co-polarized arrangement to reduce the footprint of the wireless system, while reducing the degradation in the cross-coupling between the waveguides. Also, the 3D antenna 1302 includes openings 1314, 1316, 1318, and 1320 that are oriented in a co-polarized arrangement and matching with the respective openings 1306, 1308, 1310, and 1312. The 3D antenna 1302 also include an isolation structure 1330, which includes a set of cavities/trenches configured as short circuit stubs, abutting the waveguides having the openings 1306, 1308, 1310, and 1312.

In this description, the term “couple” may cover connections, communications or signal paths that enable a functional relationship consistent with this description. For example, if device A provides a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal provided by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described herein as including one or more semiconductor elements (such as transistors), one or more passive elements (such as resistors, capacitors and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end-user and/or a third party.

Certain components may be described herein as being of a particular process technology, but these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in series or in parallel between the same two nodes as the single resistor or capacitor.

Uses of the phrase “ground voltage potential” in this description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

Modifications are possible in the described examples, and other examples are possible, within the scope of the claims.

What is claimed is:

1. A device comprising:
a substrate including:
opposite first and second surfaces, the first surface including metal pads;
a dielectric layer between the first and second surfaces;
an opening extending through the dielectric layer and connecting between the first and second surfaces, the opening including first and second ridge structures, each of the first and second ridge structures extending with a uniform cross-section along the opening.

2. The device of claim 1, wherein each of the first and second ridge structures extends symmetrically relative to one another along the opening and reaches the first and second surfaces.

3. The device of claim 1, wherein:
the first ridge structure is on a first side of the opening,
the second ridge structure is on a second side of the opening; and
the first and second sides are opposite to each other.

4. The device of claim 3, wherein the first ridge structure extends along a middle line of the first side, and the second ridge structure extends along a middle line of the second side.

5. The device of claim 1, wherein the opening is configured to be a waveguide, and dimensions of a footprint of the opening are based on a cut off frequency of the waveguide.

6. The device of claim 1, further comprising an isolation structure adjacent to the opening.

7. The device of claim 6, wherein the isolation structure includes a cavity opening towards the second surface.

8. The device of claim 7, further comprising a metal member between the opening and the cavity.

9. The device of claim 7, further comprising a dielectric material in the cavity.

10. The device of claim 9, further comprising a metal layer covering a sidewall and a bottom of the cavity.

11. The device of claim 9, further comprising a metal layer opposing the cavity opening.

12. The device of claim 11, wherein the dielectric material is a first dielectric material, and the device further comprises a second dielectric material between the metal layer and the first surface.

13. The device of claim 7, wherein the opening is a first opening, and the substrate includes a second opening through the dielectric layer, and the second opening connects between the first and second surfaces; and
wherein the device further comprises:
a first metal layer covering a first sidewall of the first opening, the first metal layer extending along the first opening and reaching the first and second surfaces; and
a second metal layer covering a second sidewall of the second opening, the second metal layer extending along the second opening and reaching the first and second surfaces; and
wherein the first and second metal layers provide a sidewall of the cavity.

14. The device of claim 13, further comprising a third metal layer and a fourth metal layer on the second surface, the third metal layer joining the first metal layer, and the fourth metal layer joining the second metal layer;
wherein the third metal layer and the fourth layer are spaced apart and define a third opening connected to the cavity.

15. The device of claim 14, wherein the third metal layer has angled edges, the fourth metal layer has a straight edge, and the angled edges and the straight edge are on opposite sides of the opening.

16. The device of claim 7, wherein the isolation structure includes a trench structure surrounding the opening, the trench structure opening towards the second surface, and the device further includes a metal layer covering a sidewall and a bottom of the trench structure, and the cavity is part of the trench structure.

17. The device of claim 1, and further comprising:
a packaged semiconductor device coupled to the metal pads via interconnects, the packaged semiconductor including a signal patch facing the opening, and the interconnects surround the opening, and
an antenna mounted on the second surface.

18. The device of claim 17, wherein:
the opening is a first opening;
the antenna has an antenna surface facing the second surface; and
the antenna includes:
a second opening extending from the antenna surface aligned with the first opening, and
a trench structure opening towards the antenna surface and surrounding the second opening.

19. The device of claim 18, wherein the trench structure is a first trench structure;
wherein the substrate includes a second trench structure extending towards the second surface and surrounding the first opening; and
the first trench structure are aligned with the second trench structure.

20. The device of claim 18, further comprising a dielectric material in the second trench.

21. The device of claim 1, wherein the substrate includes a printed circuit board (PCB).

22. A device comprising:
a substrate including:
opposite first and second surfaces, the first surface including metal pads;
a first metal layer on the second surface, the first metal layer including an opening;
a network of interconnects between the first and second surfaces and coupled to the metal pads;
a dielectric layer between the first and second surfaces and surrounding the network of interconnects, the dielectric layer including a first dielectric material;
a cavity in the dielectric layer that extends from the opening, the cavity including a second dielectric material; and
a second metal layer that covers a side surface and a bottom surface of the cavity, the second metal layer joining the first metal layer.

23. The device of claim 22, further comprising a third dielectric material between the bottom surface of the cavity and the first surface.

24. The device of claim 22, wherein the first dielectric material and the second dielectric material are of a same dielectric material.

25. The device of claim 22, wherein the opening is a first opening; and
wherein the device further comprises a second opening extending through the dielectric layer and connecting between the first and second surfaces, the second opening abutting cavity.

26. The device of claim 25, wherein the second metal layer forms the side surface and abuts the second opening.

27. The device of claim 26, further comprising a trench structure surrounding the second opening, the trench structure opening towards the second surface, and the cavity is part of the trench structure.

28. The device of claim 26, and further comprising:
a packaged semiconductor device coupled to the metal pads via interconnects, the packaged semiconductor device including a signal launch facing the second opening, and the interconnects surround the second opening; and
an antenna mounted on the second surface.

29. The device of claim 28, wherein:
the antenna has an antenna surface facing the second surface; and
the antenna includes:
a third opening extending from the antenna surface aligned with the second opening; and
a trench structure opening towards the antenna surface and surrounding the third opening.

30. The device of claim 29, wherein the trench structure is a first trench structure;
wherein the substrate includes a second trench structure extending towards the second surface and surrounding the second opening, the second trench structure including the cavity; and
wherein the first trench structure are aligned with the second trench structure.

31. The device of claim 22, wherein the substrate includes a printed circuit board (PCB).
